(19) United States
(12) Patent Application Publication
(10) Pub. No.: US 2009/0197356 A1
(43) Pub. Date: Aug. 6, 2009

(54) Substrate positioning on a vacuum chuck

(75) Inventors: Won B. Bang, Gilroy, CA (US); Yen-Kun Victor Wang, Union City, CA (US)

Correspondence Address: SHIRLEY L. CHURCH, ESQ., P.O. BOX 81146, SAN DIEGO, CA, 92138, US

(73) Assignee: Applied Materials, Inc.

(21) Appl. No.: 12/383,623

(22) Filed: Mar. 27, 2009

Related U.S. Application Data
(63) Continuation of application No. 11/230,588, filed on Sep. 20, 2005.

(51) Int. Cl. C23C 16/52; B05C 11/115; H01L 21/66

(52) U.S. Cl. 438/14; 427/8; 118/696; 257/E21.521

(57) ABSTRACT

We have discovered a method of using the vacuum chuck/heater upon which a substrate wafer is positioned to determine whether the wafer is properly placed on the vacuum chuck. The method employs measurement of a rate of increase in pressure in a confined space beneath the substrate. Because the substrate is not hermetically sealed to the upper surface of the vacuum chuck/heater apparatus, pressure from the processing chamber above the substrate surface tends to leak around the edges of the substrate and into the space beneath the substrate which is at a lower pressure. A pressure sensing device, such as a pressure transducer is in communication with a confined volume present beneath the substrate. The rate of pressure increase in the confined volume is measured. If the substrate is well positioned on the vacuum chuck/heater apparatus, the rate of pressure increase in the confined volume beneath the substrate is slow. If the substrate is not well positioned on the vacuum chuck/heater apparatus, the rate of pressure increase is more rapid.

This application is a continuation application of U.S. application Ser. No. 11/230,588, filed on Sep. 20, 2005, entitled: “Substrate Placement Determination Using Substrate Backside Pressure Measurements”, which is currently pending.

### BACKGROUND OF THE INVENTION

1. Field of the Invention

The present invention pertains to a method of determining whether a substrate has been properly positioned upon a substrate support structure such as a vacuum chucking support structure.

2. Brief Description of the Background Art

During deposition of thin films on semiconductor substrates, such as silicon wafers, stresses created during the deposition of the thin film can cause the wafer to bow if the wafer is not properly attached to the support structure used to hold the wafer in place. In thin film deposition processes, frequently the semiconductor substrate is processed while held in place on the surface of a vacuum chuck/heater assembly. Misplacement of a semiconductor wafer, for example, on the vacuum chuck/heater assembly permits uneven leakage of flowing gases around the edge of the wafer. The uneven leakage contributes to non-uniform film deposition, which tends to cause bowing of the wafer. The bowing of the wafer causes edges of the wafer to lose contact with the heater and the edge of the wafer becomes cooler than the center of the wafer. This leads to increasing film deposition non-uniformity. In some instances the bowing may be sufficiently severe that the film deposition process has to be aborted. Semiconductor equipment manufacturers devised a heated vacuum chuck to prevent bowing from occurring. However, use of the heater/vacuum chuck requires proper placement of the wafer on the center of the heater/vacuum chuck, or the heated vacuum chuck may not prevent bowing. Proper placement does not always occur, because typically the wafers are handled by automated robots which are used to place the wafer on the heater/vacuum chuck. Misplacement of the wafer by the robot is difficult to detect.

In Japanese Patent Application No. P2001-50732, filed Aug. 6, 1999 and published Feb. 23, 2001, titled “Position-Sensing Device”, the inventors describe a device for sensing the position for various parts of equipment that require positioning for product manufacture, inspection and the like. The inventors claim to have solved the technical problems related to a misplaced article by providing a position-sensing device that can reliably sense a positioning status without being limited by the shape of the product, while effectively preventing displacement, so that manual adjustment of the product is not necessary. The technical means for solving the problems is said to consist in that, in a position-sensing device that senses whether a member is placed in a prescribed position that corresponds with the placement section in which the placed member is positioned with surface contact, a suction opening is provided in a suction path to which suction is applied by a suction apparatus and a pressure sensor is also provided that senses a drop in pressure in the suction path.

Example embodiments include a substrate on which an electronic component is mounted, the aforementioned placement section comprises multiple boss parts that support the bottom surface of the aforementioned substrate at multiple positions, and the aforementioned suction opening in the suction path is formed in the center of each boss part. Examples of this include a rectangular plate-shaped substrate as the placed member, which is structured such that any type of electronic component, e.g. a relay or capacitor, is mounted as appropriate on the top surface. This may be a so-called card edge type connector that fits the edge part on both long sides of the substrate. With reference to a FIG. 1, it is mentioned that a substrate-shaped recess (rectangular) into which a substrate is inserted and removed from above may be formed in the top surface of a substrate-positioning block which is used to limit movement from front to back and left to right. A boss part which serves as the placement section, with a flat top surface that projects above the bottom surface is positioned at each of four comers of the substrate-shaped recess. The boss parts are constituted so that the substrate is positioned and held at a prescribed height above the bottom surface. The pressure sensor, which is said to sense a drop in pressure in the suction path, corresponding to the placement sections on which a member is positioned with surface contact, is illustrated in FIG. 2 as pressure sensor 21. The four boss parts which contain a suction path opening all feed into a single suction path line which is monitored by pressure sensor 21.

In the present instance, we are concerned with the misplacement of a substrate also, but the substrate is one which is in a process chamber where a vacuum chuck is used to secure the substrate during processing of the substrate. The tolerances required in the present instance are far more restrictive than in the application described in the published Japanese reference discussed above. In particular, the processing chamber in which the heater/vacuum chuck is present is generally one in which vapor deposited thin films or coatings are applied, and the concern is whether the vapor which forms the thin film will be able to leak around the edges of the wafer in a non-uniform manner so that the film applied will not be uniform, or so that portions of the back side of the wafer become coated. As discussed above, misplacement of a substrate on a vacuum chuck used to hold the substrate for processing may lead to non-uniform film deposition and to coating of a portion of the backside of the wafer, resulting in bowing of the wafer. Misplacement may occur when the “hand off” from a wafer handling robot is not precise and the wafer does not land properly on the surface of the heater/vacuum chuck which supports the wafer during the thin film vapor deposition process. Where the Japanese reference described above pertains to an end-use application in which placement accuracy must be sufficient to hold the card shaped member in position on the boss parts, the present application placement has to be so precise that vapors cannot leak unevenly around the edge of the wafer when a vacuum is pulled upon the back surface of the wafer. The increase in degree of difficulty in providing even sealing of a wafer surface around its entire periphery is readily apparent. Further, in the present application, if there is a serious misplacement of the substrate on the vacuum chuck, with a large flow of film-forming precursor in the leak area, the wafer processing chamber and auxiliary apparatus can be damaged in an intolerable manner. As a result, the ability to detect misplacement of the substrate, such as a semiconductor wafer, on the heater/vacuum chuck requires a sensitivity to enable detection of a significant leak rate of the kind which may occur when the wafer is misplaced. Further, it is important to have the ability to detect the leak rate very rapidly.

### BRIEF DESCRIPTION OF THE DRAWINGS

FIG. 1 shows a schematic top view of a vacuum chuck/heater 100 surface 102 of the kind on which a 300 mm semiconductor wafer rests for a thin film deposition process.

FIG. 2 is a schematic side view of one embodiment of a fluid flow system 200 of the kind which can be used to measure whether a semiconductor wafer is properly placed on top of the vacuum chuck/heater surface. The system 200 shown in FIG. 2 is one for a processing chamber which processes two semiconductor wafers at a time.

FIG. 3 shows graphs 300 and 320, respectively, each graph showing a comparison of the rate of pressure change in a small volume space which was in communication with the back side of a semiconductor wafer substrate which was properly placed, compared with a semiconductor wafer which was not properly placed. Graph 300 shows data for placement of wafers on a first vacuum chuck, illustrated as 254 in FIG. 2. Graph 320 shows data for placement of wafers on a second vacuum chuck, illustrated as 204 in FIG. 2.

FIGS. 4A through 4D provide a comparative illustrations related to the graphs 300 and 320. FIG. 4A shows that there is no backside wafer coating when there is proper wafer placement on the vacuum chuck illustrated as 254 in FIG. 2. FIG. 4B shows the build up of coating on the back side of the wafer when the wafer placement is poor. FIG. 4C shows that there is no backside wafer coating when there is proper wafer placement on the vacuum chuck illustrated as 204 in FIG. 2. FIG. 4D shows the backside wafer coating on one edge of the wafer when there is a leak in the seal on that edge due to improper wafer placement on the vacuum chuck.

### DETAILED DESCRIPTION OF EXEMPLARY EMBODIMENTS OF THE INVENTION

As a preface to the detailed description presented below, it should be noted that, as used in this specification and the appended claims, the singular forms “a”, “an”, and “the” include plural referents, unless the context clearly dictates otherwise.

Use of the term “about” herein indicates that the named variable may vary to ±10%.

We have discovered a method of using the vacuum chuck/heater upon which a substrate wafer is positioned to determine whether the substrate is properly placed on the vacuum chuck/heater. Frequently the substrate is a semiconductor wafer which is centered on a vacuum chuck/heater. The method employs a measurement of a rate of change in pressure in a volumetric space which is in communication with the surface of the substrate which is in direct contact with the vacuum chuck/heater. Typically this surface of the substrate is a lower surface (back side) of the substrate, while the upper surface of the substrate is being processed to alter its characteristics.

When the vacuum chuck/heater is one which is present in an Applied Materials Producer thin film deposition chamber for a 300 mm substrate, operated at a pressure in the range of about 400 Torr to 600 Torr (by way of example), with a constant gas flow to the deposition chamber in the range of 20 slm of gas, typically He/O₂ (by way of example), a nominal rate of pressure increase in the volumetric space which is in excess of 60 Torr per minute indicates that the substrate wafer is mis-positioned to an extent that it needs to be repositioned prior to thin film deposition on the substrate. When the processing apparatus and substrate orientation in the processing apparatus are as described above, the nominal pressure in the process chamber volume which is in contact with the upper surface of the substrate may range from about 0.3 Torr to about 600 Torr. Just prior to initiation of deposition of a thin film by chemical vapor deposition, for example, this pressure typically ranges from about 200 Torr to about 600 Torr, more typically from about 400 Torr to about 600 Torr. The pressure on the back side of the substrate, which is in contact with the vacuum chuck/heater apparatus, is lower, because of the vacuum applied to accomplish the vacuum chucking. Typically the pressure in the space beneath the substrate, and in conduits in communication with this space, is in the range of about 0.3 Torr to about 15 Torr. More typically the pressure in the space beneath the substrate is in the range of about 5 Torr to about 8 Torr. The amount of difference in the pressure present in the process chamber in contact with the upper surface of the substrate, and the pressure present in a volumetric space, such as a conduit, which is in communication with the lower surface of the substrate, will depend on the processing apparatus and the process being carried out. However, one skilled in the art can apply the present invention so long as there is a difference in these two pressures. Preferably, there is an ability to maintain a constant first pressure on the substrate surface which is being processed (typically the upper surface of the substrate), and an ability to measure a rate of change in the lower second pressure in a volumetric space in communication with the lower surface of the substrate. When it is desired to determine whether the substrate is properly placed on the vacuum chuck/heater apparatus which supports the substrate during processing, the application of a source of vacuum to the space beneath the substrate is discontinued. Because the substrate is not hermetically sealed to the upper surface of the vacuum chuck/heater apparatus, pressure from the processing chamber above the substrate surface tends to leak around the edges of the substrate and into the space beneath the substrate, including into conduits which are in communication with such space. A pressure measurement device, such as a pressure transducer, is present in a volumetric space which is in communication with the lower surface of the substrate. The rate of pressure increase in the volumetric space which is in communication with the lower surface of the substrate is measured. If the substrate is well positioned on the vacuum chuck/heater apparatus, the rate of pressure increase in the volumetric space in communication with the lower surface of the substrate is slow. If the substrate is not well positioned on the vacuum chuck/heater apparatus, the rate of pressure increase is more rapid. A comparison of the rate of pressure increase for a given substrate position with an acceptable rate of pressure increase for a well positioned substrate provides an indication of whether the substrate needs to be repositioned on the vacuum chuck/heater apparatus. The nominal rate increase which is acceptable will depend on the particular process which is being carried out in the process chamber.

With respect to an Applied Materials Producer thin film deposition chamber for a 300 mm substrate, operated at a pressure in the range of about 400 Torr, with a constant gas flow to the deposition chamber of 20 slm of gas (typically He/O2), an acceptable nominal rate of pressure increase in the volumetric space in communication with the lower surface of the substrate is less than about 60 Torr per minute. Generally, the rate of pressure increase ranges between about 5 Torr per minute and 60 Torr per minute. This rate of pressure increase was determined empirically, by watching the substrate during thin film deposition for an indication of problems in film deposition, which is indicative of misplacement of a substrate on the vacuum chuck.

Two indicators were used to correlate the rate of pressure increase in the volumetric space in communication with the substrate to a misplaced substrate on the vacuum chuck. One of the indicators was the uniformity in thickness across the substrate of the thin film which was deposited on the substrate. A second indicator was an uneven build up of coating material over a portion of the back side of the substrate. Either of these variables or a combination of these variables may be used as an indicator for thin film deposition processes. When the substrate is misplaced on the vacuum chuck, the deposited film thickness is not uniform over the substrate surface. When the substrate is misplaced, typically a portion of the back side of the substrate has a film/coating on it. A correlation between the rate of pressure increase and a processed substrate which fails to meet specification may be developed for any process of interest, and it is our intent that the process to which the invention is applied not be limited to a thin film deposition process only.

For a vacuum chucking apparatus different in size from the apparatus described above, with a substrate having a different peripheral edge exposure distance, or an apparatus where gas flows or operational process chamber pressures are different, the rate of pressure change in the volumetric space in communication with the non-processing surface of the wafer will typically be different. However, one skilled in the art can determine, with minimal experimentation, what the maximum tolerable rate of increase in pressure is, in view of the present disclosure.

Typically the vacuum chuck assembly is adapted to support a round semiconductor wafer. However, the present invention is applicable to other shapes of substrates than round shapes. The method provides a rapid means of determination, typically in less than a minute, of whether the substrate is properly placed on the vacuum chuck.

While the invention is described with respect to a processing chamber used to deposit thin films on the substrate, by sub-atmospheric chemical vapor deposition (SACVD), various methods of thin film/coating deposition are intended to be included, such as general CVD, PECVD, Metal CVD, and ALD, by example and not by means of limitation. The method may also be used to determine substrate placement in processing applications other than thin film/coating deposition, where a substrate is vacuum chucked during processing. It is not our intent that the method be limited to processing chambers for thin film deposition. However, this is one of the most important applications for the method of the invention, since non-uniform film deposition and migration of coating materials onto the back side of the substrate during film deposition causes not only problems with respect to performance of the coated substrate and warping of the substrate, but also may cause severe damage to surfaces and functional fluid flow channels of a vacuum chuck supporting the substrate during processing.

An Apparatus for Practicing the Invention

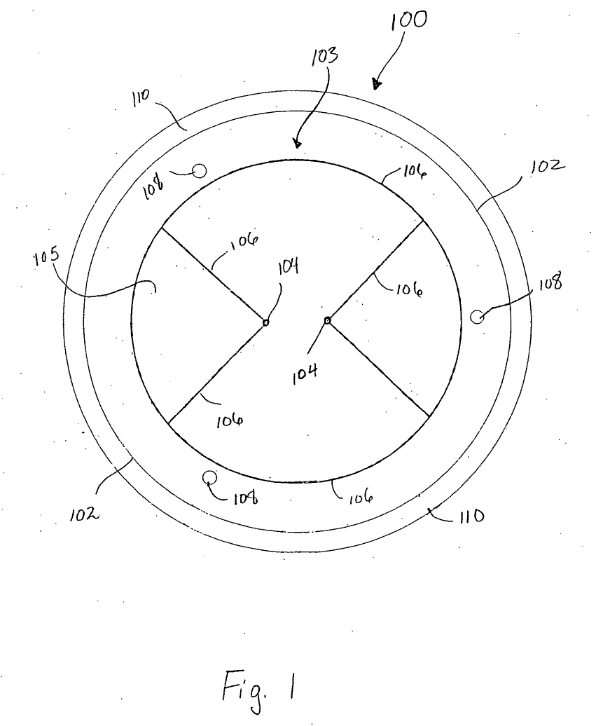

The embodiment example apparatus used for experimentation during development of the method was a Producer SACVD processing chamber, available from Applied Materials, Inc., Santa Clara, Calif. Referring to FIG. 1, the vacuum chuck/heater apparatus 100 which supports a substrate (not shown) during processing (in this instance during deposition of a thin film of silicon dioxide) typically includes a central section 103 on which the substrate (not shown) resides. The periphery of the substrate, when properly positioned, is aligned with the periphery 102 of central section 103 of the vacuum chuck/heater 100. Surrounding central section 103 is a lip 110. The substrate (not shown) sits in a recess formed by the lip 110 in combination with central section 103. It is also possible to use a vacuum chuck which does not include a lip, for some processing applications.

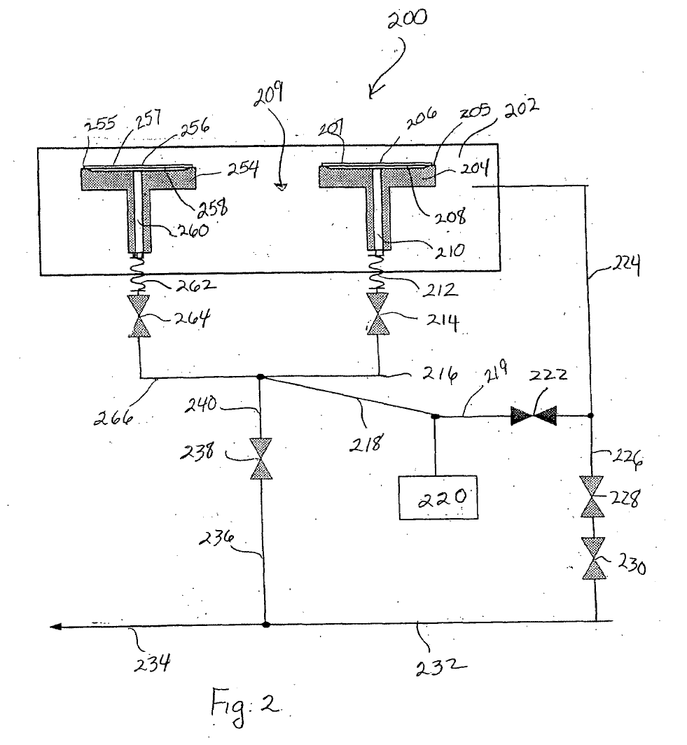

The central section 103 of the vacuum chuck/heater 100 also includes two chucking ports 104, which are orifices through which reduced pressure (vacuum) is applied to assist in holding the sample (not shown) down on the surface of the vacuum chuck/heater 100 during the thin film deposition process. Chucking grooves 106 further apply the reduced pressure to an increased surface area of a substrate present over the central section 103 of vacuum chuck/heater 100. Typically at least the upper portion of the vacuum chuck is a ceramic material, and the heater (not shown), which may be used to increase the temperature of the substrate during processing, is a resistance heater which is embedded in the ceramic material. With reference to FIG. 2, the substrate may be de-chucked by creating a balance in the pressure on the top and bottom surfaces of the substrate (by opening valves 222, 264, and 214, for example) and then using the substrate lifting pins (not shown) which are raised up through lift pin holes 108.

When the hand off of a substrate wafer onto the surface of the vacuum chuck/heater 100, typically from a robotic handling device (not shown), is inaccurate, and the periphery of the wafer does not lie along the circumference 102 of the central section 103 of the vacuum chuck/heater, the amount of chucking force is not evenly applied over the surface of the substrate wafer (not shown) and one edge of the wafer may be slightly raised off the upper surface 105 of vacuum chuck/heater 100. Even a slight lifting of an edge of the substrate wafer may result in the leakage of thin film forming materials onto the back side of the substrate wafer and into the vacuum chucking grooves 106 and chucking ports 104, and even further down into the system (not shown) which is used to apply the vacuum to the chucking ports 104. Formation of thin film coatings on these internal elements of the vacuum chuck/heater 100 and auxiliary vacuum application system can permanently damage the apparatus or require substantial down time for cleaning. As a result, if it is known that a substrate wafer is not properly positioned on the vacuum chuck/heater 100, the thin film deposition is delayed until the substrate wafer can be properly positioned.

There are optical techniques which can be used to monitor the position of a substrate wafer on the vacuum chuck/heater 100; however in a thin film deposition chamber, the optics become coated by the film deposition process, and maintaining a clear line of sight to the wafer substrate is a problem. We tried monitoring a decrease in the vacuum at a location beneath the upper surface 105 of the vacuum chuck/heater 100, but when a vacuum is constantly applied, the amount of leakage of gases from the process chamber into the vacuum system may be insufficient to indicate when a misplacement of a substrate wafer has occurred.

We developed a method of indicating substrate wafer misplacement in which the application of vacuum to the vacuum chuck/heater is discontinued, and a rate of increase in pressure in a vacuum line conduit is measured. The volume of the vacuum line conduit is sufficiently small that a flow of gases from the process chamber into the vacuum line conduit (or other small volume space in communication with the surface of the substrate wafer which is not being processed, the wafer back side) is readily sensed using a pressure sensor. The pressure in the process chamber is held constant by a gas feed to the process chamber. This keeps a gas flow leaking into the small volume space in communication with the wafer back side, which is being watched for an increase in pressure. The pressure sensor used to detect a pressure increase in the small volume space is typically a pressure transducer which measures a pressure up to at least 20 Torr, and more typically up to about 50 Torr, when the processing apparatus is the Producer apparatus described herein. The pressure in the vacuum line conduit (or other small volume space in communication with the wafer back side) may be measured and plotted as a function of time. In the alternative, the time required to reach the maximum pressure measured by the transducer may be measured. Based on the rate of pressure increase, and the amount of film-forming materials which are observed to leak beneath a substrate wafer in relation to the rate of pressure increase, one skilled in the art can determine a rate of pressure increase which is not acceptable, and provide for repositioning of the substrate wafer when the rate of pressure increase exceeds the acceptable rate.

FIG. 2 is a schematic side view of one embodiment of a fluid flow system 200 of the kind which can be used to measure whether a semiconductor wafer 206 or 256 is properly placed on the upper surface 205 or 255 of the vacuum chuck/heater 204 or 254, respectively. The system 200 shown in FIG. 2 is one for a processing chamber which processes two semiconductor wafers 206 and 256. The number of wafers processed in a process chamber at one time depends on the system design. We have determined that it is advantageous to test the placement of each wafer independently in terms of accuracy of measurement. With this in mind, the fluid flow system 200 is designed to permit isolation of vacuum chuck/heater 204 or vacuum chuck/heater 254 from the wafer placement testing system at a given time.

For example, shut off valve 264 may be closed and shut off valve 214 may be open so that testing of the placement of wafer 206 on vacuum chuck heater 204 may be carried out. Wafer 206 rests on the upper surface 205 of vacuum chuck/heater 204, leaving a space 208 beneath wafer 206 which leads to central conduit 210. Line 234 leads to a vacuum pump (not shown). The reduced pressure (vacuum) applied to line 234 may be used to reduce the pressure in line 236 and in line 232. Line 236 leads to vacuum valve 238 which is normally open during vacuum chucking of wafer 206, during thin film deposition on the upper surface 207 of wafer 206. This permits employing a reduced pressure in line 216 leading to shut-off valve 214, which is also open during the thin film deposition process. The reduced pressure (vacuum) is applied through small volume conduit 212 into central conduit 210, and from there into chucking ports 104 and chucking grooves 106 of the kind shown in FIG. 1. The reduced pressure in line 240 is also transferred through line 218 to pressure sensor 220 and from there through line 219 to by-pass valve 222. If by-pass valve 222 is open, the reduced pressure will also be applied to line 224, which leads to processing chamber 209. If by-pass valve 222 is closed and vacuum valve 238 is closed, and shut-off valve 214 is open, gases which are maintained at a constant pressure in process chamber 209 by a gas addition device (not shown) cause a rise in the pressure in conduit 210, small volume conduit 212, line 216, and line 218 leading to pressure sensor 220. The rate of pressure increase is determined either by incremental measurement of pressure as a function of time or by measurement of the amount of time required to reach a given pressure. This rate of pressure increase is compared with an acceptable value, which is determined by the process being carried out in the process chamber. One of skill in the art can, with minimal experimentation, determine a maximum acceptable rate of pressure increase for a given process step, such as a thin film deposition step. Typically, when shut-off valve 214 to vacuum chuck/heater 204 is open, shut off valve 264 to vacuum chuck/heater 254 is closed, so that chuck/heater 254 is isolated and it is clear that a problem rate of pressure increase is attributable to a mis-positioning of wafer 206 on the upper surface 205 of vacuum chuck/heater 204.

Wafer 256 rests on the upper surface 255 of vacuum chuck/heater 254, leaving a space 258 beneath wafer 256 which leads to central conduit 260. A reduced pressure (vacuum) applied to line 234 may be used to reduce the pressure in line 236 and in line 232. Line 236 leads to vacuum valve 238 which is normally open during vacuum chucking of wafer 256, during thin film deposition on the upper surface 257 of wafer 256. This permits employing a reduced pressure in line 266 leading to shut-off valve 264, which is also open during the thin film deposition process. The reduced pressure (vacuum is applied through small volume conduit 262 into central conduit 260, and from there into chucking ports 104 and chucking grooves 106 of the kind shown in FIG. 1. The reduced pressure in line 240 is also transferred through line 218 to pressure sensor 220 and from there through line 219 to by-pass valve 222. If by-pass valve 222 is open, the reduced pressure will also be applied to line 224, which leads to processing chamber 209. If by-pass valve 222 is closed and vacuum valve 238 is closed, and shut-off valve 264 is open, gases which are maintained at a constant pressure in process chamber 209 by a gas addition device (not shown) cause a rise in the pressure in conduit 260, small volume conduit 262, line 266, and line 218 leading to pressure sensor 220. The rate of pressure increase is determined either by incremental measurement of pressure as a function of time or by measurement of the amount of time required to reach a given pressure. This rate of pressure increase is compared with an acceptable value, which is determined by the process being carried out in the process chamber. One of skill in the art can, with minimal experimentation, determine a maximum acceptable rate of pressure increase for a given process step, such as a thin film deposition step. Typically, when shut-off valve 264 to vacuum chuck/heater 204 is open, shut off valve 214 to vacuum chuck/heater 204 is closed, so that chuck/heater 204 is isolated and it is clear that a problem rate of pressure increase is attributable to a mis-positioning of wafer 256 on the upper surface 255 of vacuum chuck/heater 254.

Line 232 is typically under reduced pressure due to the vacuum pump (not shown) which is employed to reduce the pressure in line 234. Throttle valve 230 is used to help control the amount of vacuum which may be applied to line 224 leading to processing chamber 209 when isolation valve 228 is open. By controlling these valves in combination with the valves discussed above with reference to the individual vacuum chuck/heaters 204 and 254, the various functions desired within the system may be maintained. Control of the valves to provide the functions desired is carried out by a programmed controller (not shown) of the type known in the art, which typically permits an operator to manipulate the system as desired.

Data For Example Embodiments

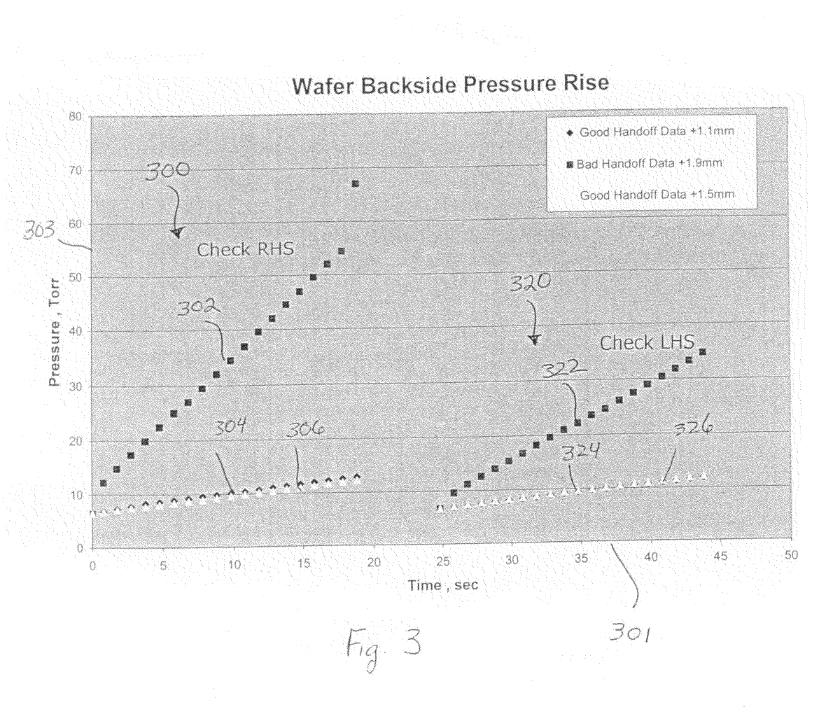

FIG. 3 shows graphs 300 and 320, with each graph showing a comparison of the rate of pressure change in a small volume space in communication with the substrate back side, for a semiconductor wafer which is properly placed compared with a semiconductor wafer which is not properly placed. For both graphs, the pressure in Torr measured by the pressure sensor in the small volume space (a conduit in communication with the substrate back side) is shown on axis 303 as a function of the time in seconds, shown on axis 301, during which pressure from the process chamber is permitted to leak into the small volume space conduit. In graph 300, curve 302 is illustrative of a rapid increase in the pressure in the small volume space conduit, which is due to misplacement of a wafer on the upper surface of a first vacuum chuck (illustrated as 254 in FIG. 2) upon handoff of the wafer from a robotic wafer handling tool. The increase in pressure was about 45 Torr in 20 seconds. Curves 304 and 306 are representative of a slow increase in pressure in the small volume space conduit, which was observed when a wafer was properly placed on the vacuum chuck. The increase in pressure was only about 7 Torr in 20 seconds. In graph 320, curve 322 is illustrative of a rapid increase in the pressure in the small volume space conduit, due to mis-placement of a wafer on a second vacuum chuck (illustrated as 204 in FIG. 2). The increase in pressure was about 29 Torr in 20 seconds. Curves 324 and 326 are representative of a slow increase in pressure in the small volume space conduit, which occurred when the wafer was properly placed on the vacuum chuck. The increase in pressure was only about 5 Torr in 20 seconds.

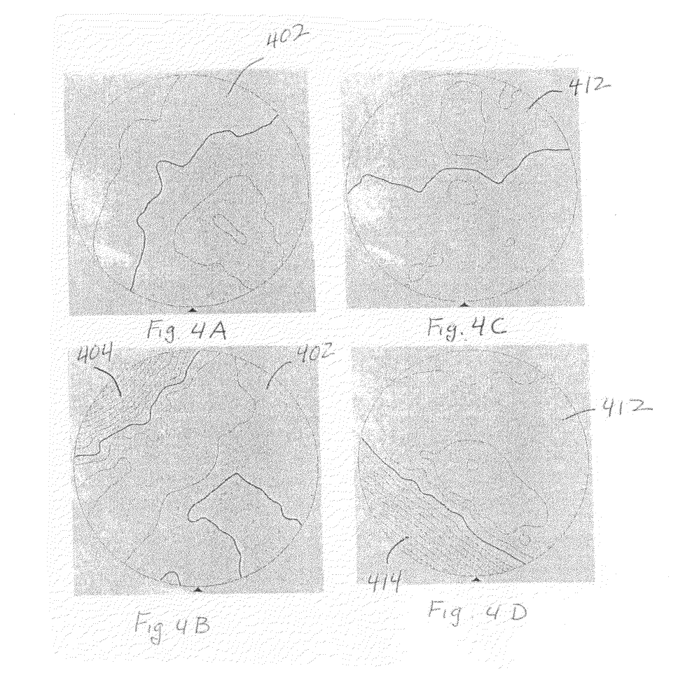

FIGS. 4A through 4D provide a comparative illustrations related to the graphs 300 and 320. FIG. 4A shows that there is no backside wafer coating on wafer 402 when there is proper wafer placement on the vacuum chuck illustrated as 254 in FIG. 2. FIG. 4B shows the build up 404 of coating on the back side of the wafer 402 when the wafer placement is poor. FIG. 4C shows that there is no backside wafer coating on wafer 412 when there is proper wafer placement on the vacuum chuck illustrated as 204 in FIG. 2. FIG. 4D shows the build up 414 of backside wafer coating on one edge of the wafer 412 when there is a leak in the seal on that edge due to improper wafer placement on the vacuum chuck, which is illustrated as 204 in FIG. 2.

While the invention has been described in detail above with reference to several embodiments, various modifications within the scope and spirit of the invention will be apparent to those of working skill in this technological field. Accordingly, the scope of the invention should be measured by the appended claims.

1. A method of determining whether a substrate is properly placed upon a surface of a vacuum chuck, said method comprising:
maintaining an essentially constant pressure in a process chamber, where an upper surface of said vacuum chuck is exposed to the pressure in said process chamber;
creating a reduced pressure in a confined small volume space which is in communication with the bottom surface of said substrate;
isolating said confined small volume space from the source which was used to create said reduced pressure;
measuring a rate of pressure increase in or a time period required to reach a given pressure in said confined small volume space; and
correlating said rate of pressure increase or said time period to an indicator of the satisfactory or unsatisfactory placement of said substrate on said vacuum chuck.

2. A method in accordance with claim 1, wherein said rate of pressure increase or a set point pressure is measured using a pressure transducer which is in communication with a portion of said confined small volume space.

3. A method in accordance with claim 1, wherein a thin film coating is being applied on a substrate in said process chamber, and said indicator of the satisfactory or unsatisfactory placement of said substrate on said vacuum chuck is a previously-developed correlation between a rate of pressure increase in or a time period required to reach a given pressure in said confined small volume space and an amount of coating which accumulated on the back side of said substrate.

4. A method in accordance with claim 3, wherein said substrate is selected from the group consisting of a semiconductor wafer, a flat panel display substrate, and a solar cell substrate.

5. A method in accordance with claim 4, wherein said substrate is a semiconductor wafer.

6. A method in accordance with claim 1, wherein said pressure in said process chamber ranges between about 200 Torr and about 600 Torr.

7. A method in accordance with claim 6, wherein said reduced pressure in said confined small volume space beneath the bottom surface of said substrate initially ranges between about 0.3 Torr and about 15 Torr.

8. A method in accordance with claim 7, wherein a rate of pressure increase in said confined small volume space due to said pressure in said process chamber is less than about 60 Torr per minute.

9. A method in accordance with claim 8, wherein said rate of pressure increase ranges from about 5 Torr per minute to less than 60 Torr per minute.

10. A method in accordance with claim 1, wherein said indicator of the satisfactory or unsatisfactory placement of said substrate on said vacuum chuck is a previously-developed correlation between a rate of pressure increase in or a time period required to reach a given pressure in said confined small volume space and deposited thin film thickness uniformity, amount of back side wafer coating, or a combination thereof.

11. A method in accordance with claim 10, wherein said indicator is thin film uniformity, and wherein an unacceptable rate of pressure increase or a time period required to reach a given pressure in said confined small volume space correlates with a film thickness uniformity which varies by more than about 2%.

12. An apparatus which is used to determine whether a substrate is properly placed upon a surface of at least one vacuum chuck present within a thin film deposition process chamber, said apparatus comprising:
a) a process chamber which is sealed from ambient conditions so that a first pressure in contact with a surface of a substrate which is to be processed can be controlled;
b) said surface of said at least one vacuum chuck including at least one orifice which is in communication with a central conduit in present within said vacuum chuck;
c) a small volume conduit in direct communication with said central conduit, where a volume of said small volume conduit is sized to be sufficiently small that a flow of gases from said process chamber into said small volume conduit creates a second pressure which serves as an indicator of whether misplacement of a substrate has occurred;
d) at least one vacuum system which is used to create said second pressure, and which may be in communication with said process chamber or said small volume conduit, or both;
e) an isolation device which permits isolation from said vacuum system of said small volume conduit which is in communication with said vacuum chuck orifice and isolation of said process chamber from said vacuum system used to create said second pressure;
f) a pressure sensing device which is in communication with said small volume conduit, and which measures the pressure in said small volume conduit; and
g) a programmed controller in communication with devices which make up said apparatus, wherein said programmed controller references an indicator correlated to said pressure in said small volume conduit, determines whether said substrate is properly placed on said vacuum chuck surface, and uses a determination to improve processing within said thin film deposition process chamber.

13. An apparatus in accordance with claim 12, wherein said first pressure is below atmospheric pressure.

14. An apparatus in accordance with claim 13, wherein said at least one vacuum system which is used to create said pressure which is less than atmospheric pressure, in said small volume conduit is also used to create a pressure which is less than atmospheric pressure in said process chamber.

15. An apparatus in accordance with claim 14, wherein a valving system is present which is adapted to enable said second pressure in said conduit to be less than said first pressure in said process chamber.

16. An apparatus in accordance with claim 12, wherein said indicator is correlated to a rate of increase of pressure in said small volume conduit.

17. An apparatus in accordance with claim 12, wherein said indicator is correlated to a time required to reach a nominal, specified pressure in said small volume conduit.

18. An apparatus in accordance with claim 16, wherein an acceptable range of said indicator correlates with film thickness uniformity determined empirically from films deposited on a series of substrates.

19. An apparatus in accordance with claim 17, wherein an acceptable range of said indicator correlates with film thickness uniformity determined empirically from films deposited on a series of substrates.

20. An apparatus in accordance with claim 18, wherein said indicator correlates with back side coating deposition occurrence as determined empirically from measurement of a series of substrates.

21. An apparatus in accordance with claim 19, wherein said indicator correlates with back side coating deposition occurrence as determined empirically from measurement of a series of substrates.

22. An apparatus in accordance with claim 12, wherein said process chamber contains a plurality of vacuum chucks, wherein each vacuum chuck is in communication with an individual small volume conduit which is in communication with a pressure sensing device.
